(19) United States
(12) Patent Application Publication
(10) Pub. No.: US 2006/0138683 A1
(43) Pub. Date: Jun. 29, 2006

(54) Fabrication method of light emitting diodes

(76) Inventor: Chih-Ming Hsu, Taoyuan (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/218,434

(22) Filed: Sep. 6, 2005

(30) Foreign Application Priority Data
Dec. 24, 2004 (TW) 93140478

(51) Int. Cl. H01L 21/00

(52) U.S. Cl. 257/E21.132; 438/46

(57) ABSTRACT

The present invention discloses a fabrication method of light emitting diodes, which comprises the following steps: firstly, providing three sapphire wafers with each sapphire wafer having a substrate and an epitaxial layer; turning the sapphire wafers upside down and sticking an adhesive tape onto each epitaxial layer; attaching three sapphire wafers to a ceramic work piece; performing coarse grinding on the substrates with a machining table; performing fine grinding on the substrates with a polishing disc; removing the substrate completely with etching; unloading the remaining epitaxial layers and the adhesive tapes, and turning them upside down again, and stripping off the adhesive tapes; forming a conductor via joining the epitaxial layer with an electrically-conductive layer of a metal or another wafer. Thereby, the brightness of LED can be increased; the fabrication process can be accelerated; the yield can be promoted; and the cost can be reduced.

### BACKGROUND OF THE INVENTION

1. Field of the Invention

The present invention relates to a fabrication method of light emitting diodes, particularly to a fabrication method of light emitting diodes, which can promote the yield.

2. Description of the Related Art

Owing to the consciousness of the global energy crisis, searching for high energy-efficient illuminators to replace the conventional ones has become an important subject. As semiconductor can perform the energy conversion between electricity and light, therefore, many applications have been derived, such as the light emitting diode (LED). LED has the advantages of energy-saving, high vibration resistance, long service life, and less heat generated. Recently, Ultra-High-Brightness LED (UHB-LED) and LED's of different wavelengths, such as white LED and blue LED, have been developed to replace the conventional incandescent lamp or halogen lamp.

The quality of UHB-wite/blue LED is dependent on the quality of gallium nitride, and the quality of epitaxial gallium nitride is dependent on the surface finishing quality of the sapphire substrate used in the fabrication of epitaxial gallium nitride. The crystalline structure of sapphire (monocrystalline alumina) is similar to that of epitaxial gallium nitride, and sapphire also has the high temperature resistance demanded by the fabrication process of epitaxial gallium nitride; thus, the sapphire wafer becomes a critical material in fabricating white/blue LED.

Superior surface finishing of a sapphire wafer is needed in growing high-brightness LED. However, owing to its high hardness and high melting point, sapphire is very hard to machine. Therefore, the machining of the sapphire wafer plays an important role in the fabrication of LED.

At present, the substrate of a sapphire wafer is removed with a laser. However, the laser-removing method is very slow and raises the fabrication time and cost.

Accordingly, the present invention proposes a fabrication method of light emitting diodes to overcome the abovementioned problems.

### SUMMARY OF THE INVENTION

The primary objective of the present invention is to provide a fabrication method of light emitting diodes, wherein it is after sticking an adhesive tape to the sapphire wafer that the substrate of the sapphire wafer is ground and removed, and after the substrate has been removed, the epitaxial layer is joined with a metal or another wafer to form a conductor. Thereby, the brightness of LED can be promoted.

Another objective of the present invention is to provide a fabrication method of light emitting diodes, wherein the substrate can be really completely removed so that the brightness can be promoted, and it is after the substrate has been ground and removed that the electrically-conductive layer is formed so that the yield can be raised.

Further objective of the present invention is to provide a fabrication method of light emitting diodes, wherein the substrate of the sapphire wafer is removed not via a laser method but via an etching method. Thus, the fabrication process of LED can be accelerated, and the fabrication cost thereof is lowered.

To achieve the abovementioned objectives, the present invention proposes a fabrication method of light emitting diodes, which comprises the following steps: providing a sapphire wafer having a substrate and an epitaxial layer; turning the sapphire wafer upside down and sticking an adhesive tape onto the epitaxial layer; attaching the adhesive tape to a ceramic work piece and fixing the work piece to a machining table; grinding the substrate; unloading the ceramic work piece from the machining table and thinning the substrate; completely removing the substrate to reveal the epitaxial layer via an etching method; turning the epitaxial layer and the adhesive tape upside down again, and stripping off the adhesive tapes from the epitaxial layer; and lastly, forming an electrically-conductive layer on the bottom surface of the epitaxial layer.

To enable the objectives, technical contents, characteristics, and accomplishments of the present invention to be more easily understood, the embodiments of the present invention are to be described below in detail in cooperation with the attached drawings.

### BRIEF DESCRIPTION OF THE DRAWINGS

FIG. 1(a) to FIG. 1(g) are schematic diagrams of the steps of the fabrication method of light emitting diodes of the present invention.

### DETAILED DESCRIPTION OF THE INVENTION

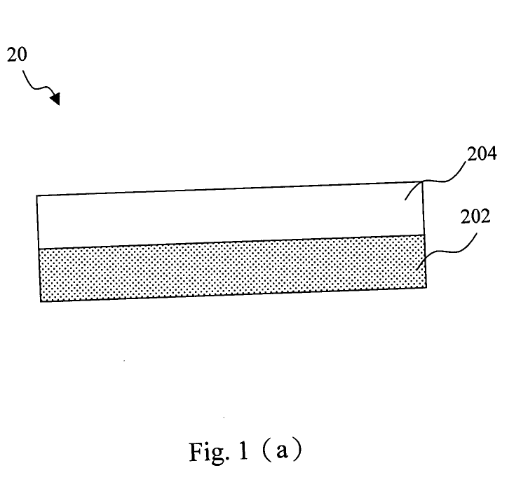

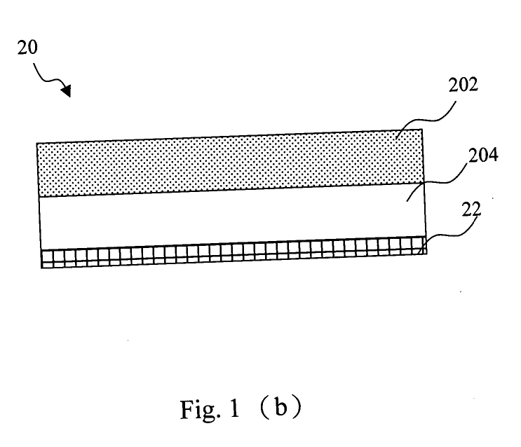

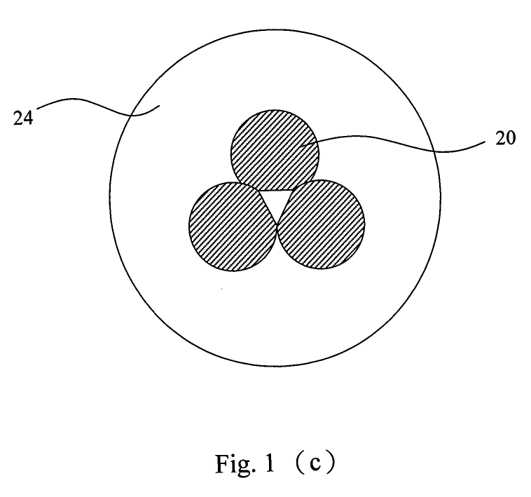

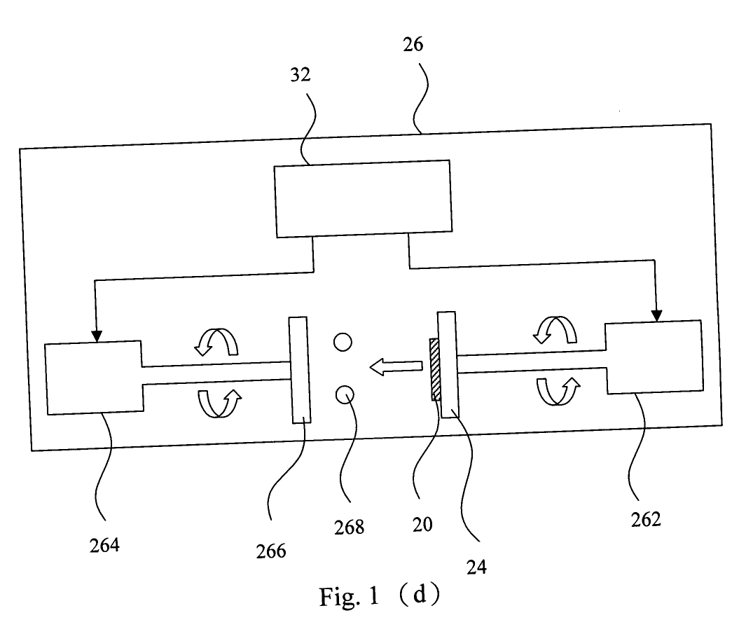

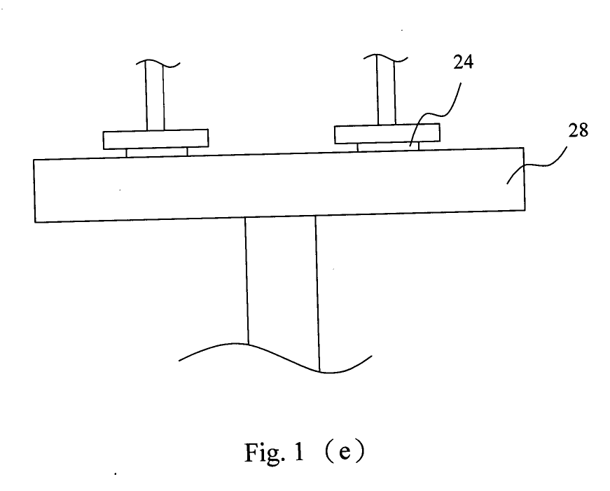

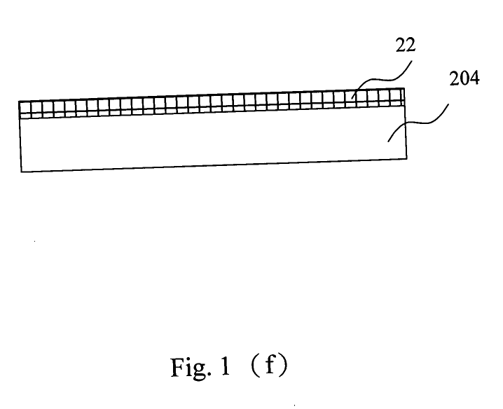

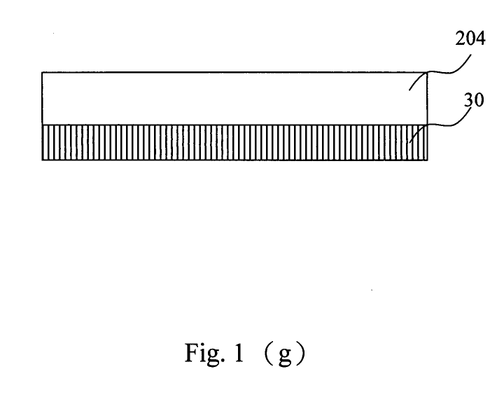

The present invention proposes a fabrication method of light emitting diodes. Refer to from FIG. 1(a) to FIG. 1(g) schematic diagrams of the steps of the fabrication method of light emitting diodes of the present invention. Firstly, three sapphire wafers 20 are provided with each sapphire wafer 20 having a substrate 202 and an epitaxial layer 204 on the substrate 202, as shown in FIG. 1(a) a section view of the sapphire wafer 20; next, three sapphire wafers 20 are turned upside down, and an adhesive tape 22 is stuck onto each of the epitaxial layers 204 of the sapphire wafers 202, as shown in FIG. 1(b); next, three sapphire wafers 20, which has been stuck onto the adhesive tapes 22, are attached to a ceramic work piece 24 with wax, and fixed to the ceramic work piece 24 via pressing the sapphire wafers 20 with a pressure ranging from 1 to 10 kg/cm², as shown in FIG. 1(c); the ceramic work piece 24 is fixed to a machining table 26, and the substrates 202 of the sapphire wafers 20 are roughly ground to a thickness of from 50 to 200 μm, as shown in FIG. 1(d); next, a fine grinding follows, and the ceramic work piece 24 is unloaded from the machining table 26 and disposed on a polishing disc 28, and the substrates 202 of the sapphire wafers 20 are thinned with a polishing solution to a thickness less than 10 μm, as shown in FIG. 1(e); next, the substrate 202 is completely removed to reveal the epitaxial layer 204 via an etching method, such as a dry etching method or a wet etching method; next, the epitaxial layers 204 and the adhesive tapes 22 stuck thereto are unloaded from the ceramic work piece 24 and turned upside down again, and the adhesive tapes 22 are stripped off from the epitaxial layers 204, as shown in FIG. 1(f); and lastly, an electrically-conductive layer 30, such as a cupric, golden, molybdenum, or aluminum layer or another wafer, is formed on the bottom surface of each epitaxial layer 204, and the epitaxial layer 204 and the electrically-conductive layer 30 are integrated into a conductor having higher brightness, as shown in FIG. 1(c).

Refer to FIG. 1(d) again. The machining table 26 has a first transmission device 262 and a second transmission device 264, wherein both the first and the second transmission devices 262, 264 may be 20 motors. The second transmission device 264 has a grinding wheel 266, and the grinding wheel 266 may comprises diamonds. The ceramic work piece 24 is fixed onto the first transmission device 262 via a vacuum-suction method, and the grinding wheel 266 is disposed corresponding to the sapphire wafers 20 on the ceramic work piece 24. The first transmission device 262 can drive the ceramic work piece 24 to move back and forth for some distance according to grinding parameters stored in a control device 32, and the grinding parameters include thickness ground off, grinding time, and a grinding mode. The control device 32 controls the second transmission device 264 to drive the grinding wheel 266 to rotate and move left or right. Thereby, the sapphire wafers 20 and the grinding wheel 266 can move to each other, and the substrates 202 of the sapphire wafers 20 can be roughly ground. Further, two coolant nozzles 268 are installed in the machining table 26 to spray a liquid coolant in order to cool the sapphire wafers 20 and the grinding wheel 266 lest the temperature rise too much in the rough grinding.

The present invention proposes a fabrication method of light emitting diodes, wherein a coarse grinding and a fine grinding is used to thin the substrate, and an etching method is used to completely remove the substrate; it is only after sticking an adhesive tape and finishing the grinding of the substrate that the electrically-conductive layer is formed on the epitaxial layer. Thereby, the yield and the brightness thereof can be promoted. Further, the substrate of the sapphire wafer is removed not via a laser method as the conventional technology does but via an etching method. Thus, the fabrication process of LED can be accelerated, and the fabrication cost thereof is lowered.

Those embodiments described above are to clarify the present invention to enable the persons skilled in the art to understand, make, and use the present invention but not intended to limit the scope of the present invention. Any equivalent modification and variation according to the spirit of the present invention is to be included within the scope of the claims of the present invention stated below.

What is claimed is:

1. A fabrication method of light emitting diodes, comprising the following steps:
providing at least one sapphire wafer having a substrate and an epitaxial layer;
turning said sapphire wafers upside down and sticking an adhesive tape onto said epitaxial layer;
fixing said adhesive tape to a ceramic work piece;
fixing said ceramic work piece to a machining table;
grinding said substrate of said sapphire wafer;
unloading said ceramic work piece, and thinning said substrate;
removing said substrate completely to reveal said epitaxial layer via an etching method;
turning said epitaxial layer and said adhesive tape, and stripping off said adhesive tape from said epitaxial layer; and
forming at least one electrically-conductive layer on the bottom surface of said epitaxial layer so that said epitaxial layer and said electrically-conductive layer can form a conductor.

2. The fabrication method of light emitting diodes according to claim 1, wherein said electrically-conductive layer is either a metallic layer or a wafer.

3. The fabrication method of light emitting diodes according to claim 1, wherein said adhesive tape is attached to said ceramic work piece with a wax and fixed to said ceramic work piece with a pressure.

4. The fabrication method of light emitting diodes according to claim 3, wherein said pressure ranges from 1 to 10 kg/cm².

5. The fabrication method of light emitting diodes according to claim 1, wherein said machining table further comprising a first transmission device, and said ceramic work piece is fixed to said first transmission device with a vacuum-suction method, and said first transmission device drives said ceramic work piece to move back and forth.

6. The fabrication method of light emitting diodes according to claim 5, wherein said first transmission device is a motor.

7. The fabrication method of light emitting diodes according to claim 5, wherein said machining table further comprising a control device and a second transmission device disposed corresponding to said first transmission device, and said control device is used to control said first transmission device and said second transmission device.

8. The fabrication method of light emitting diodes according to claim 1, wherein said machining table further comprising a second transmission device, and said second transmission device has a grinding wheel disposed corresponding to said sapphire wafer on said ceramic work piece, and said second transmission device drives said grinding wheel to rotate and move left or right.

9. The fabrication method of light emitting diodes according to claim 8, wherein said second transmission device is a motor.

10. The fabrication method of light emitting diodes according to claim 8, wherein said machining table further comprises at least one coolant nozzle to spray a liquid coolant in order to cool said sapphire wafer and said grinding wheel.

11. The fabrication method of light emitting diodes according to claim 8, wherein said grinding wheel comprises diamond.

12. The fabrication method of light emitting diodes according to claim 8, wherein said machining table further comprises a control device and a first transmission device disposed corresponding to said second transmission device, and said control device is used to control said first transmission device and said second transmission device.

13. The fabrication method of light emitting diodes according to claim 1, wherein said substrate is ground to a thickness of from 50 to 200 μm.

14. The fabrication method of light emitting diodes according to claim 1, wherein said substrate is thinned via that said ceramic work piece is disposed on a polishing disc and thinned with a polishing solution to reduce the thickness of said substrate of said sapphire wafer.

15. The fabrication method of light emitting diodes according to claim 1, wherein said substrate is thinned to a thickness less than 10 μm.

16. The fabrication method of light emitting diodes according to claim 1, wherein said etching method is either a dry etching method or a wet etching method.
